(19) United States
(12) Patent Application Publication
(10) Pub. No.: US 2005/0285661 A1
(43) Pub. Date: Dec. 29, 2005

(54) Gate drive circuits for high efficiency power converters

(76) Inventor: Ernest H. Wittenbreder JR., Flagstaff, AZ (US)

Correspondence Address: Ernest H. Wittenbreder, 3260 S Gillenwater Drive, Flagstaff, AZ, 86001, US

(21) Appl. No.: 10/878,448

(22) Filed: Jun. 28, 2004

(51) Int. Cl. H01L 29/80

(52) U.S. Cl. 327/434

(57) ABSTRACT

Several novel gate drive circuits are revealed that accomplish optimal gate drive timing for zero voltage switches, both for the case in which there is sufficient drive energy to complete a turn on transition to zero volts and for the case for which there is insufficient drive energy available to complete a zero voltage turn on transition. Other related circuits are revealed which provide clamping to eliminate ringing and overshoot for secondary side placed ZVS drive chokes using a novel circuit and a winding of the ZVS drive choke used for gate drive for a synchronous rectifier. A boot strap gate drive energy circuit is revealed that provides gate drive energy for high side switches with reference terminals that swing both above and below ground. Gate drive circuits that rely on timing information from an auxiliary choke used for ZVS drive energy are also revealed.

### BACKGROUND OF THE INVENTION

1. Field of the Invention

The subject invention generally pertains to electronic power conversion circuits, and more specifically to gate drive circuits for high frequency, switched mode electronic power converters. Some of the subject matter of this application was first revealed in patent application Ser. No. 10/137,908. Some of the subject matter of this application was first revealed in Disclosure Document Number 527396.

2. Description of Related Art

During the critical turn on transition of a main switch in a zero voltage switching (ZVS) power converter circuit the drain to source voltage of the main switch falls, driven by stored energy in a magnetic circuit element. At the onset of this turn on transition, an auxiliary switch or another main switch is turned off initiating the transition. An optimal gate drive circuit will keep the main switch off during the transition and turn on the switch immediately at the instant that the drain to source voltage of the main switch reaches zero volts. One common method of gate drive for zero voltage switching power converters is to use a pulse width modulated (PWM) controller IC, such as the UCC3580 which allows for a programmable delay between the on time of the main switch and the on time of the auxiliary switch. The fixed on time will be optimal for one condition of line and load, since the energy available and the energy needed to complete a zero voltage turn on transition is dependent on both line voltage and load current. As a practical matter a fixed delay time is less than optimal for most conditions. The problem is this: if the delay is too short, then the switch will turn on before the voltage has dropped all the way to zero and switching losses will occur, or, if the switch is turned on too late, the voltage on the main switch may reach zero but then begin to rise up again after the energy available to drive the transition has dissipated, which also results in significant switching losses. What is needed is a circuit that can sense the main switch voltage and turn on the switch at exactly the right time every time. One improvement to the use of a PWM controller with a fixed dead time delay is to add a gate drive circuit with a gate resistor and a turn off speed up diode, as illustrated in FIG. 1. During a turn on transition, current flows upward (towards the top of the page) in the drain of the mosfet M_{ZVS}. This drain current causes the voltage across the mosfet to fall which causes the intrinsic gate drain capacitor to discharge. A current I_{CGD} flows in the gate drain capacitor which forces the voltage at the gate of the mosfet to fall, holding the mosfet off, during the turn on transition. When the transition is complete the current I_{CGD} becomes zero and no longer has an effect on the gate voltage. In common practice the current I_{CGD} is not sufficient to keep the mosfet off by itself, but it does add delay to the turn on, only when delay is needed, and thereby provides a benefit. This effect is more effective for larger values of R_{DELAY}. Large values of R_{DELAY} are not practical because the gate must be turned on quickly or the drain to source voltage will rise up again and switching losses will be incurred. A combination of a small gate resistor with a speed up turn off diode and a fixed delay circuit is the most common method used.

One circuit that solves the problem of gate timing for a zero voltage switching converter is illustrated in FIG. 2. FIG. 2 uses a relatively large value gate resistor, R_{START}, which enables the converter to start after a delay for starting up the converter. After the converter is in operation there is energy available to drive zero voltage turn on transitions and the FIG. 2 circuit senses the drain to source voltage of the main switch and turns on a P channel mosfet to quickly turn on the main switch when its drain source voltage has dropped to zero volts. One shortcoming of the FIG. 2 circuit is that the threshold voltage of the P channel mosfet is typically in the range of 1 to 3 volts and the gate drive source voltage is typically in the range of 10 to 15 volts so that the FIG. 2 circuit initiates a turn on transition when the drain to source voltage of the main switch is about 7 volts or higher. Since there is a delay in the turn on of the main switch due to the finite gate to source capacitance and limited current of the gate drive source the advance turn on is not a problem and can be a benefit for higher voltage off line power supplies, but for lower voltage converters the higher turn on threshold can be a significant problem. For a converter that operates form a 12 volt bus, an industry standard bus voltage, a threshold of 7 volts for both main and auxiliary switches in a zero voltage switching power converter can result in both switches being on at the same time resulting in a catastrophic cross conduction and device failure. What is needed is a circuit that provides a turn on threshold of the gate drive circuit that is at zero volts or at least much closer to zero volts.

One simple gate drive circuit that has seen use in some high volume commercial applications is shown in FIG. 9. This circuit was invented by the applicant, but no patent protection was sought by the assignee. Here an inverted PWM control signal is capacitively coupled to a high side main switch in a buck converter. The gate circuit of the high side switch contains an inverting driver that inverts the gate drive signal a second time resulting in a non-inverted gate drive signal, as desired. The key to the understanding of this simple circuit is the source voltage of the main high side switch. During a turn on transition of the main switch the voltage at the input to the driver U₂ is falling, causing the voltage at the output of U₂ and the gate of the main switch to rise. As the gate voltage of the main switch rises at the output of U₂ the main switch turns on causing the source of the main switch to rise in voltage towards V_{LINE}. As the source voltage rises the capacitor C_{DRIVE} is charged through the diode D₂, forcing the input of U₂ to stay low and the output of U₂ to stay high through the transition, as desired. One can see that the double inversion is absolutely necessary for the successful operation of this gate drive circuit. During a turn off transition of the main switch the input of U₂ is initially driven high by C_{DRIVE} and is forced to stay high during the transition as the source voltage falls and the diode D₁ discharges the capacitor C_{DRIVE}. In each case the movement of the source reinforces the initiating transition at the input of U₂, which can only occur if U₂ is an inverter, as indicated. The high side gate drive circuit is powered by the bootstrap diode D_{BOOT} and the capacitor C_{BOOT}, which is charged during the off time of the main switch when the synchronous rectifier conducts. This circuit, as shown, requires that the source of the main switch be at zero volts in order to accomplish charging of the capacitor C_{BOOT} to the proper voltage. What is needed is a more general circuit that can work in applications in which the source voltage of the high side switch is different than zero volts during the off time of the high side switch.

In a prior invention of the applicant (U.S. Pat. No. 6,650,550) a mechanism for synchronous rectifier self gate drive was revealed, illustrated in FIG. 13, using the auxiliary inductor provided for driving the zero voltage turn on transition of the main switch. After the main switch has turned on the current in the secondary circuit ramps down to zero at which time the voltage across the synchronous rectifier rises up. As the synchronous rectifier voltage rises, the output capacitance of the synchronous rectifier charges up, which creates a current in the secondary circuit opposite in direction to the direction of normal current in the secondary circuit. Associated with this current is stored energy in the inductor L_{ZVS}. The stored energy and current continue to build up in the L_{ZVS} inductor until the voltage across the L_{ZVS} inductor is zero volts, at which time the voltage across the L_{ZVS} inductor changes sign, the voltage across the synchronous rectifier continues to increase, overshooting its nominal off state voltage and creating a ringing wave form which continues until it is damped out by an intentional snubber or resistive circuit parasitics. The ringing can cause an EMC compliance failure and the overshoot can cause an over voltage failure of the synchronous rectifier. Also, the ringing in the secondary winding of the auxiliary inductor can cause an inadvertent turn on of the synchronous rectifier at the peak of the overshoot, which can result in a catastrophic failure. What is needed is an effective clamping mechanism to eliminate the overshoot and ringing.

U.S. Pat. No. 6,452,814 reveals a zero voltage switching cell that does not require a high side driven switch. An example of the use of this switching cell to an active clamp flyback converter is illustrated in FIG. 16. FIG. 16 illustrates that there is a leakage inductance element in the primary circuit that combines the effects of leakage magnetic flux from L_{MAIN} and L_{ZVS}. The effects of the leakage inductance are overshoot and ringing at the drain of the main switch, which is easily clamped, as illustrated in FIG. 16, by Z_{CLAMP1}. Each cycle a small fraction of the input energy goes into L_{LEAK} which is dissipated in Z_{CLAMP1}. An alternate method of clamping the leakage inductance energy is illustrated in FIG. 17. In the FIG. 17 circuit all of the leakage inductance energy is dissipated in R_{CLAMP}. One of the advantages of an active clamp circuit is that the energy that would otherwise be dissipated in a zener clamp or a diode RC clamp circuit is recirculated. What is needed is a simple method to actively clamp the leakage inductance in the circuit without the requirement of a high side driven active clamp switch.

U.S. Pat. No. 6,580,255 reveals a method of optimal gate drive timing that applies for the condition of insufficient drive energy to complete a zero voltage switching transition. The problem is illustrated in FIG. 27(a) and FIG. 27(b). In FIG. 27(a) the drain source voltage wave form for a transition with sufficient drive energy is illustrated. FIG. 27(b) illustrates the drain wave form for the condition in which there is insufficient drive energy to drive the voltage all the way to zero volts. If there is insufficient drive energy then the drain source voltage will reach a minimum and the voltage will rise up again until the maximum gate delay is reached and the main switch is turned on, typically with large switching loss. A circuit that provides a solution for the problem illustrated in FIG. 27 is illustrated in FIG. 26. In the FIG. 26 circuit when the drain source voltage reverses direction, current in the capacitor C₁ forward biases the transistor Q₁, which enables M_{GATE} and M_{ZVS} in turn so that the drain source voltage does not rise significantly above its minimum value and the main switch M_{ZVS} is turned on with a minimum of switching losses. There is one minor flaw in the FIG. 26 circuit that usually does not occur but can occur under some circumstances. The problem is illustrated in FIG. 28(a). What can occur is that as the switch Q₁, M_{GATE}, and M_{ZVS} begin to turn on, the drain source voltage of M_{ZVS} stops rising and begins to fall and the current to forward bias Q₁ disappears. This is a form of negative feedback that results in a slow rise in gate voltage of M_{ZVS} and a slow fall of drain source voltage of M_{ZVS}, as illustrated in FIG. 28(a). What is needed is an improvement to the FIG. 26 circuit that eliminates the negative feedback and quickly completes the turn on transition as soon as the transition is initiated.

### OBJECTS AND ADVANTAGES

An object of the subject invention is to reveal simple gate drive circuits that provide optimal switch timing for zero voltage switches.

Another object of the subject invention is to reveal simple gate drive circuits that provide optimal switch timing for the condition in which the drive energy is insufficient to complete a transition all the way to zero volts.

Another object of the subject invention is to reveal a simple gate drive circuit with a bootstrap mechanism that will work for high side switches that swing both above ground and below ground.

Another object of the subject invention is to reveal a simple clamping circuit for drive chokes placed on the secondary side in active clamp flyback converters and similar zero voltage switching power converters with secondary side placed ZVS drive chokes.

Another object of the subject invention is to reveal an active clamp gate drive circuit that provides recirculation of leakage inductance energy without the requirement for level shifting circuits or a separate gate drive transformer.

Further objects and advantages of my invention will become apparent from a consideration of the drawings and ensuing description.

These and other objects of the invention are provided by novel circuit techniques that sense the drain source voltage and the time rate of change of drain source voltage of a zero voltage switch to optimize the switch turn on timing. Also revealed are new circuits that provide effective and simple clamping of a synchronous rectifier in a ZVS power converter with secondary side placed ZVS drive choke. Also revealed are circuits that eliminate clamp circuit losses in converters with no active high side drive. Also revealed are gate drive circuits applicable to high side switches with reference terminals that swing both above ground and below ground.

### BRIEF DESCRIPTION OF THE DRAWINGS

The present invention is illustrated by reference to the drawings.

FIG. 1 illustrates a typical gate drive circuit for a ZVS switch according to the prior art containing a delay resistor and turn off speed up diode.

FIG. 2 illustrates a gate drive circuit that senses the drain source voltage of the ZVS switch and enables optimal turn on timing of the ZVS switch according to the prior art.

FIG. 3 illustrates a circuit that improves on the optimal switch timing of the FIG. 2 circuit.

FIG. 4(a) illustrates the voltage wave form of the gate drive source of the FIG. 3 circuit.

FIG. 4(b) illustrates the drain source voltage wave form of the M_{ZVS} switch of the FIG. 3 circuit.

FIG. 4(c) illustrates the gate voltage wave form of the M_{GATE} transistor of the FIG. 3 circuit.

FIG. 4(d) illustrates the gate voltage wave form of the M_{ZVS} switch of the FIG. 3 circuit.

FIG. 5 illustrates a variation of the subject invention illustrated in FIG. 3 but with a PNP bipolar transistor substituted for the P channel mosfet.

FIG. 6 illustrates an improved version of the FIG. 2 circuit that adds a zener diode to provide turn on of the M_{ZVS} switch when its drain to source voltage is closer to zero volts.

FIG. 7 illustrates a variation of the subject invention illustrated in FIG. 6 but with a PNP bipolar transistor substituted for the P channel mosfet.

FIG. 8 illustrates a variation of the subject invention illustrated in FIG. 6 which relies instead on standard logic and driver integrated circuits rather than discrete transistors and diodes to accomplish the gate drive.

FIG. 9 illustrates a bootstrapped high side gate drive circuit according to the prior art.

FIG. 10 illustrates a bootstrapped high side gate drive circuit according to the subject invention that has the capability to swing the driven high side switch both above and below ground potential.

FIG. 11(a) illustrates the source voltage wave form of the high side main switch of the FIG. 10 circuit according to the subject invention.

FIG. 11(b) illustrates the gate drive source voltage wave form of the FIG. 10 circuit according to the subject invention.

FIG. 11(c) illustrates the voltage wave form at the output of the inverting driver U_{DRIVE1} of the FIG. 10 circuit according to the subject invention.

FIG. 11(d) illustrates the voltage wave form at the output of the inverting driver U_{DRIVE2} of the FIG. 10 circuit according to the subject invention.

FIG. 11(e) illustrates the voltage wave form at the drain terminal of the mosfet M_{BOOT} of the FIG. 10 circuit according to the subject invention.

FIG. 11(f) illustrates the gate voltage wave form of the high side main switch of the FIG. 10 circuit according to the subject invention.

FIG. 12 illustrates a ZVS tapped inductor buck converter employing the gate drive circuits of FIG. 10 and FIG. 6 according to the subject invention.

FIG. 13 illustrates an active clamp flyback converter with a secondary side placed ZVS drive choke with synchronous rectifier self gate drive provided by the ZVS drive choke according to the prior art.

FIG. 14 illustrates an active clamp flyback converter with a synchronous rectifier voltage clamp circuit according to the subject invention.

FIG. 15 illustrates an active clamp flyback converter employing the synchronous rectifier voltage clamping circuit and optimal gate drive circuit of the subject invention.

FIG. 16 illustrates a ZVS flyback converter with low side switches and a zener clamp according to the prior art.

FIG. 17 illustrates a ZVS flyback converter with low side switches and a diode RC clamp according to the prior art.

FIG. 18 illustrates a ZVS boost converter with a bootstrap powered synchronous rectifier gate drive circuit with the timing information provided by the ZVS drive choke according to the subject invention.

FIG. 19 illustrates a ZVS boost converter with a bootstrap powered synchronous rectifier gate drive circuit with the timing information provided by the ZVS drive choke and with an optimal timing circuit according to the subject invention.

FIG. 20 illustrates a ZVS flyback converter with two low side switches and with an active clamp driven by a bootstrap circuit with timing derived from the ZVS drive choke and a monostable multivibrator according to the subject invention.

FIG. 21(a) illustrates the voltage wave form for the gate drive of the main switch of the FIG. 20 circuit according to the subject invention.

FIG. 21(b) illustrates the voltage wave form for the gate drive of the auxiliary switch of the FIG. 20 circuit according to the subject invention.

FIG. 21(c) illustrates the voltage wave form for the comparator output in the gate drive circuit for the active clamp switch of the FIG. 20 circuit according to the subject invention.

FIG. 21(d) illustrates the voltage wave form for the monostable multivibrator output in the gate drive circuit for the active clamp switch of the FIG. 20 circuit according to the subject invention.

FIG. 22 illustrates a gate drive circuit with optimal switch timing according to the subject invention.

FIG. 23 illustrates a variation of the FIG. 22 gate drive circuit but with a PNP bipolar transistor instead of a P channel mosfet according to the subject invention.

FIG. 24 illustrates a gate drive circuit with optimal switch timing according to the subject invention.

FIG. 25 illustrates the gate drive circuit of FIG. 24 applied to the active reset switch in a ZVS flyback converter according to the subject invention.

FIG. 26 illustrates a gate drive circuit optimal for insufficient energy turn on transitions according to the prior art.

FIG. 27(a) illustrates the drain source voltage wave form of a main switch in a ZVS power converter for a turn on transition with sufficient drive energy to complete the transition to zero voltage.

FIG. 27(b) illustrates the drain source voltage wave form of a main switch in a ZVS power converter for a turn on transition with insufficient drive energy to complete the transition to zero voltage.

FIG. 28(a) illustrates a possible drain source voltage wave form of a main switch in a ZVS power converter for a turn on transition with insufficient drive energy to complete the transition to zero voltage using the gate drive circuit of FIG. 26 showing the effects of negative feedback.

FIG. 28(b) illustrates the drain source voltage wave form of a main switch in a ZVS power converter for a turn on transition with insufficient drive energy to complete the transition to zero voltage using the gate drive circuit of FIG. 29 according to the subject invention.

FIG. 29 illustrates a gate drive circuit optimal both for turn on transitions with insufficient energy and with sufficient energy according to the subject invention.

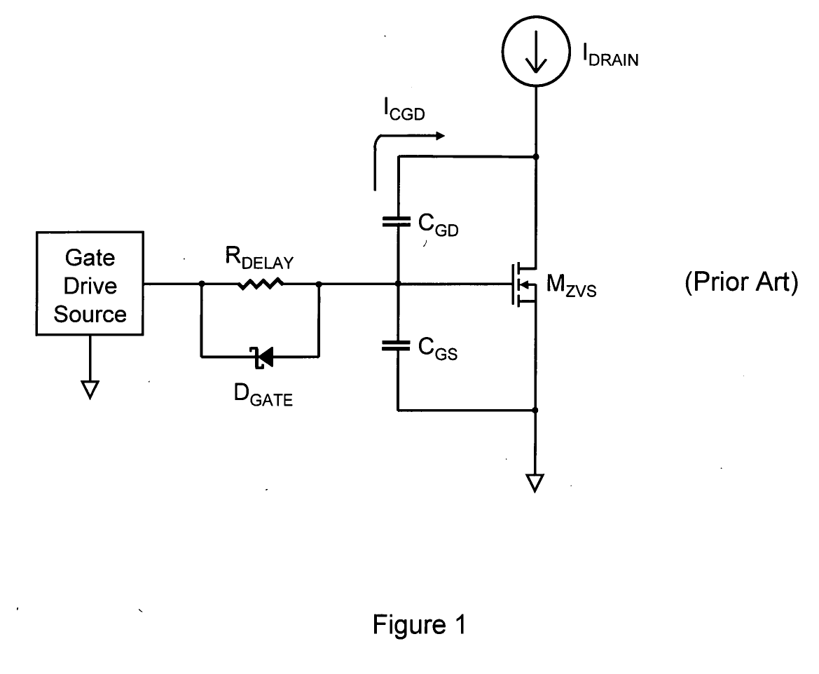

### SUMMARY

The subject invention uses drain source voltage and drain source voltage rate of change sensing techniques to provide optimal switch timing for zero voltage switches for the case with sufficient drive energy available to drive the drain source voltage to zero volts and for the case in which there is insufficient drive energy available to drive the drain source voltage to zero volts. The subject invention also reveals a method to clamp overshoot and ringing in a gate drive circuit for a secondary side synchronous rectifier which uses an auxiliary winding of a ZVS drive choke to provide self gate drive for the synchronous rectifier. The subject invention also reveals a method to provide gate drive power via a bootstrap technique applicable to high side switches that swing both above and below ground potential. The subject invention also reveals a method to drive a high side active clamp switch or synchronous rectifier using bootstrap power and timing information available from a ZVS drive choke actively driven by a low side switch thereby obviating an active high side drive level shifting circuit or a gate drive transformer.

### DESCRIPTION OF THE PREFERRED EMBODIMENTS

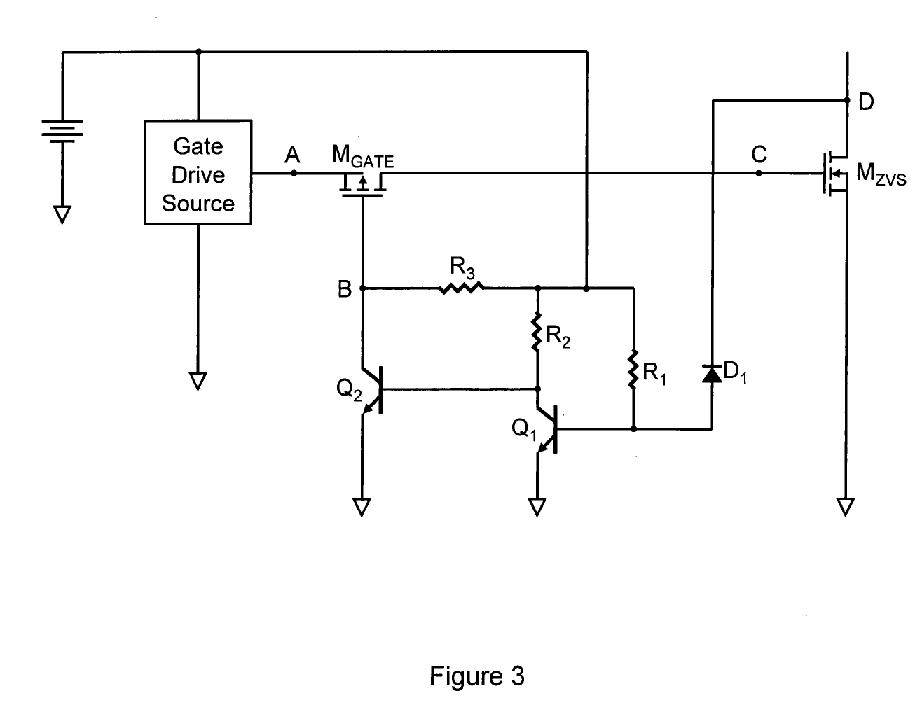

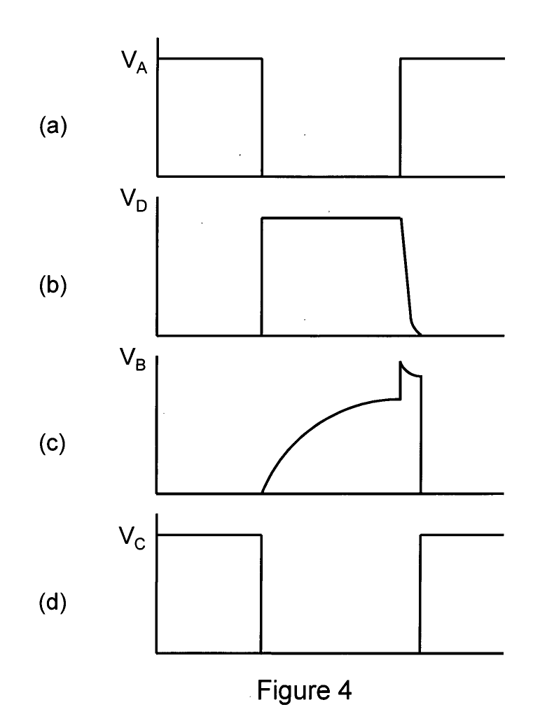

FIG. 3 illustrates a circuit wherein the gate voltage of the main switch, M_{ZVS}, is controlled or gated by the P channel mosfet, M_{GATE}. During a turn on switching transition the voltage at node A is at a level sufficient to fully enhance the gate of M_{ZVS} and the drain source voltage of the main switch, M_{ZVS}, is falling towards zero volts. At the start of the turn on transition the voltage at the gate of M_{ZVS} remains low, i.e., at or near ground potential since the P channel mosfet M_{GATE} is not enhanced, the base emitter junction of transistor Q₁ is forward biased, driven by current from R₁, Q₂ is off, since the voltage at the base of Q₂ is held low, i.e., at ground potential due to Q₁ being in an on state, and the voltage at node B is held high by R₃ holding M_{GATE} off, i.e., in a non-conducting state. When the drain voltage of M_{ZVS} falls to ground potential, i.e., zero volts, the rectifier D₁ becomes forward biased turning off Q₁. With Q₁ off the voltage at the base of Q₂ rises, driven by current provided by R₂, and Q₂ turns on, forcing the voltage at the gate of M_{GATE} to fall to ground potential, which enables M_{GATE} and allows current to flow into the gate of M_{ZVS}, thereby turning M_{ZVS} on at zero volts, which is the desired result. During a turn off transition the voltage at node A falls quickly to zero volts thereby forward biasing the intrinsic body diode of M_{GATE} which discharges the gate of M_{ZVS} forcing M_{ZVS} off immediately at the beginning of the turn off transition. As the gate voltage of M_{ZVS} falls into the threshold region of M_{ZVS} the channel of M_{ZVS} becomes a high resistance and the current in M_{ZVS} transfers from the channel of M_{ZVS} into the drain source capacitance and gate drain capacitance of M_{ZVS} and the drain source voltage of M_{ZVS} rises at a rate dependent on the drain current at the beginning of the off transition. FIG. 4(a) illustrates the voltage wave form of the controlled gate drive source at node A. FIG. 4(b) illustrates the voltage wave form of the drain voltage of the main switch M_{ZVS} at node D. Notice how the slope of the falling drain voltage decreases during the turn on transition as the available drive energy and current are depleted. FIG. 4(c) illustrates the voltage wave form at node B at the gate of the P channel mosfet, M_{GATE}. FIG. 4(d) illustrates the voltage wave form at node C at the gate of the main switch, M_{ZVS}. Notice how the voltage at node C is delayed with respect to the voltage at node A during the turn on transition.

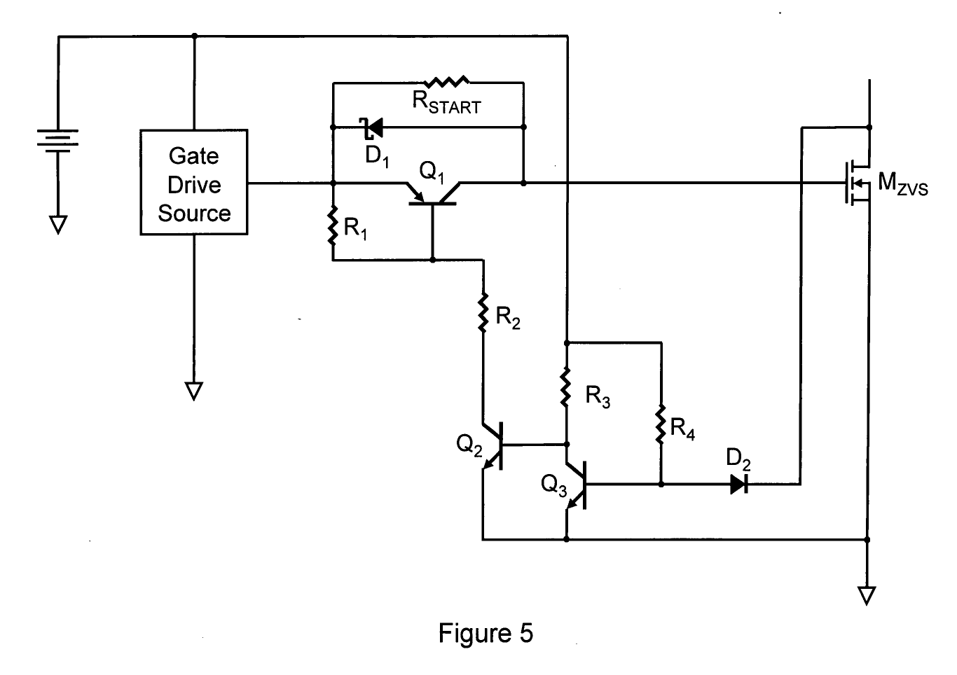

FIG. 5 illustrates a variation of the FIG. 3 circuit in which the P channel mosfet, M_{GATE}, is replaced by a PNP bipolar transistor circuit. The FIG. 5 circuit adds a start up resistor, R_{START}, which is usually necessary for starting the power converter circuit. The diode D₁ is added to provide a fast turn off transition with no delay. Q₁ and Q₂ remain in an off state and Q₃ remains in an on state after the start of the turn off transition until the drain voltage of the main switch, M_{ZVS}, falls to zero volts, at which time D₂ becomes forward biased, the current in resistor R₄ is diverted from the base of Q₃ to D₂, turning Q₃ off and diverting current from Q₃ into the base of Q₂, and Q₂ and Q₁ are turned on, thereby enabling the flow of current into the gate of M_{ZVS}.

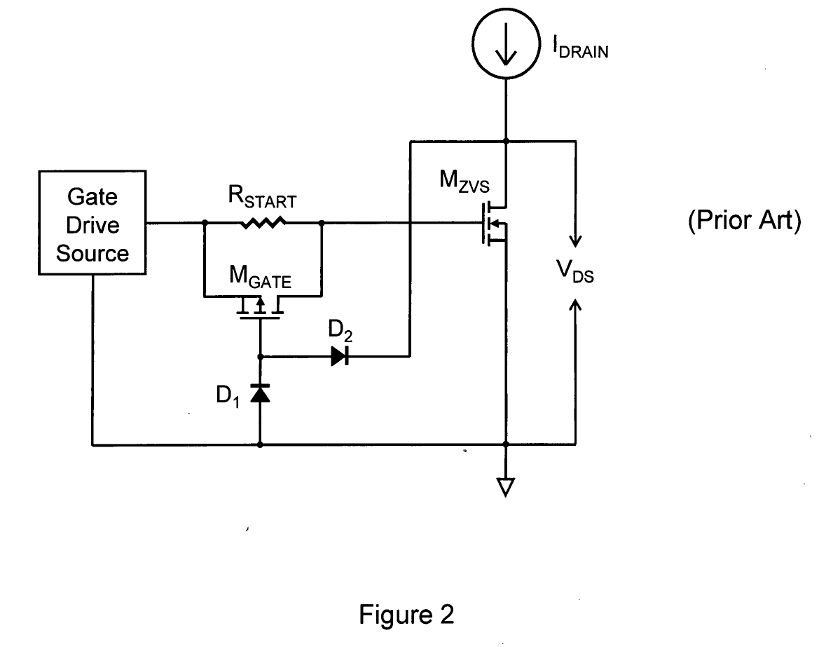

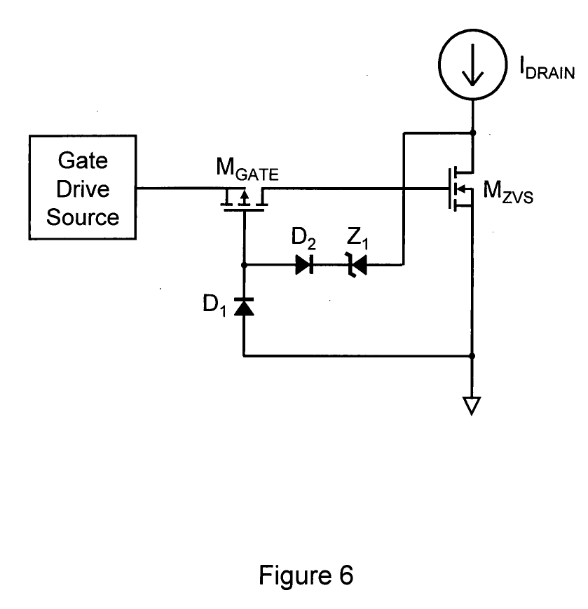

FIG. 6 is an improvement of the prior art gate drive circuit illustrated in FIG. 2. The FIG. 6 circuit adds a zener diode, Z₁, to avoid the turn on of M_{ZVS} prior to the instant that the drain voltage of M_{ZVS} reaches zero volts. A typical on voltage at the gate drive source is 10 to 15 volts. A typical gate threshold voltage for a low voltage P channel mosfet is in the range of 1 to 3 volts and a typical forward voltage for D₂ is in the range of 0.5 to 1 volt. As a result, without the zener diode the gate of M_{ZVS} will be enabled, not at zero volts, but at a voltage in the range of 6 to 13 volts which will cause some amount of turn on switching losses. It may be desirable to initiate the turn on transition at a positive voltage near to zero in some cases, since there is a finite time interval between the initiation of the turn on and the time at which the gate of the main switch is enabled due to intentional and intrinsic resistances in the gate current path and the intrinsic gate capacitance of the main switch. In some cases, particularly for converters that operate with low line voltages, the advance turn on is undesirable and can result in simultaneous conduction of a main switch and a reset switch or synchronous rectifier which can prevent proper starting of the converter or can cause a catastrophic failure. In the FIG. 6 circuit during a turn on transition the drain voltage of the main switch, M_{ZVS}, falls until the drain voltage has reached a small positive voltage near zero volts, at which time the diode D₂ begins to conduct and the zener diode Z₁ begins to avalanche. As the drain voltage of M_{ZVS} continues to fall to zero the voltage at the gate of M_{GATE} falls into and beyond the threshold region enhancing M_{GATE} and enabling current to flow to the gate of M_{ZVS}.

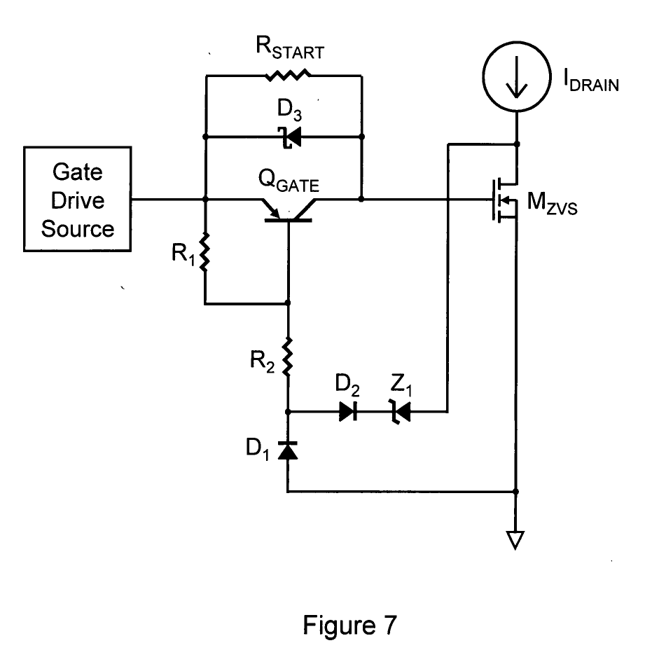

FIG. 7 illustrates a variation of the FIG. 6 circuit in which a PNP bipolar transistor circuit replaces the P channel mosfet of FIG. 6. The rectifier D₃ provides a fast turn off current path and the resistor R_{START} provides a delayed current path for starting the converter. The PNP bipolar transistor holds off the enabling of M_{ZVS} until the diode D₂ and zener diode Z₁ begin to conduct.

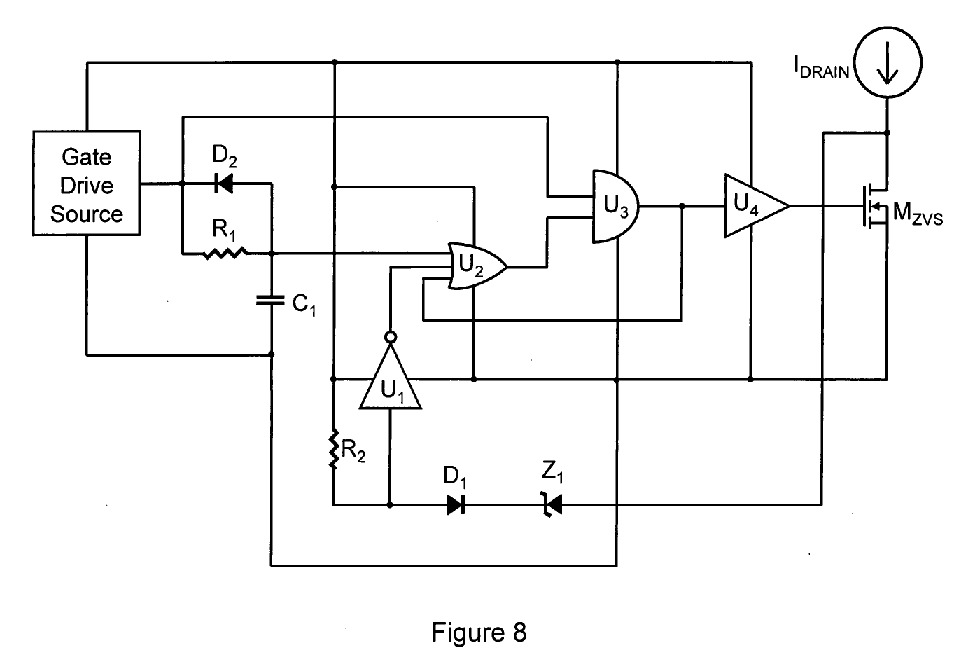

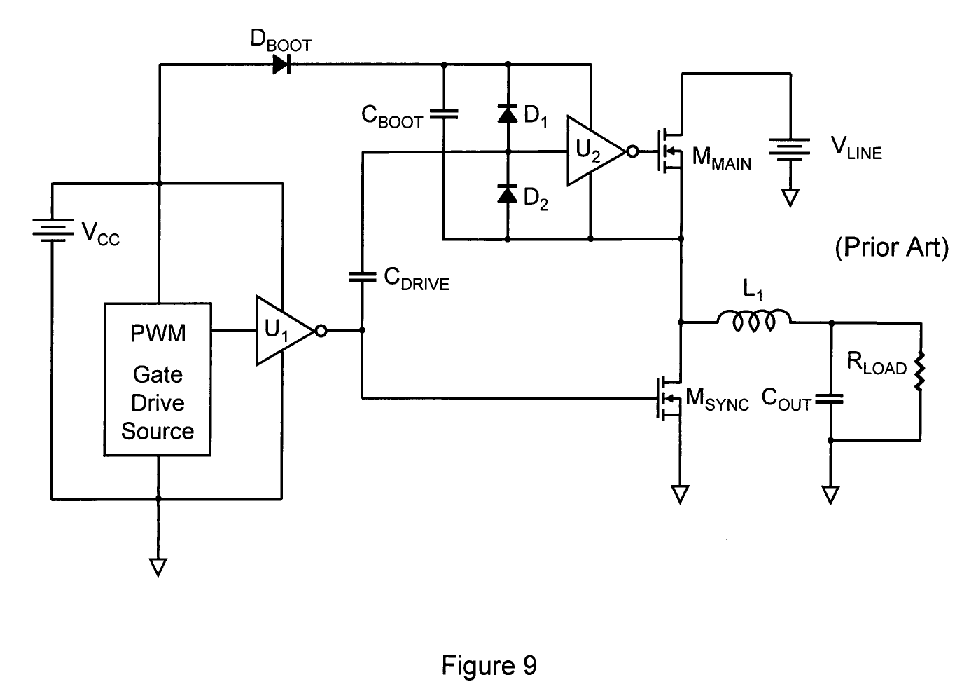

FIG. 8 illustrates another variation of the FIG. 6 circuit in which the P channel mosfet is replaced by small scale integrated logic circuits and a driver integrated circuit, U₄. In FIG. 8 R₁ and C₁ provide a maximum fixed turn on delay. Z₁ is set to provide turn on at or just slightly above zero volts for the M_{ZVS} drain voltage. The voltage at the output of the gate drive source goes high at the start of the turn on transition, but the output of the AND gate, U₃, must remain low until both inputs of U₃ are high. The output of U₂ will go high either with the output of U₁ going high or after a delay which is dependent on the values of R₁ and C₁. The output of U₁ will go high when the input to U₁ goes low. The output of U₃ is fed back to the input of U₂ so that after a turn on transition is complete the gate voltage of M_{ZVS} is latched on until the gate drive source initiates a turn off transition.

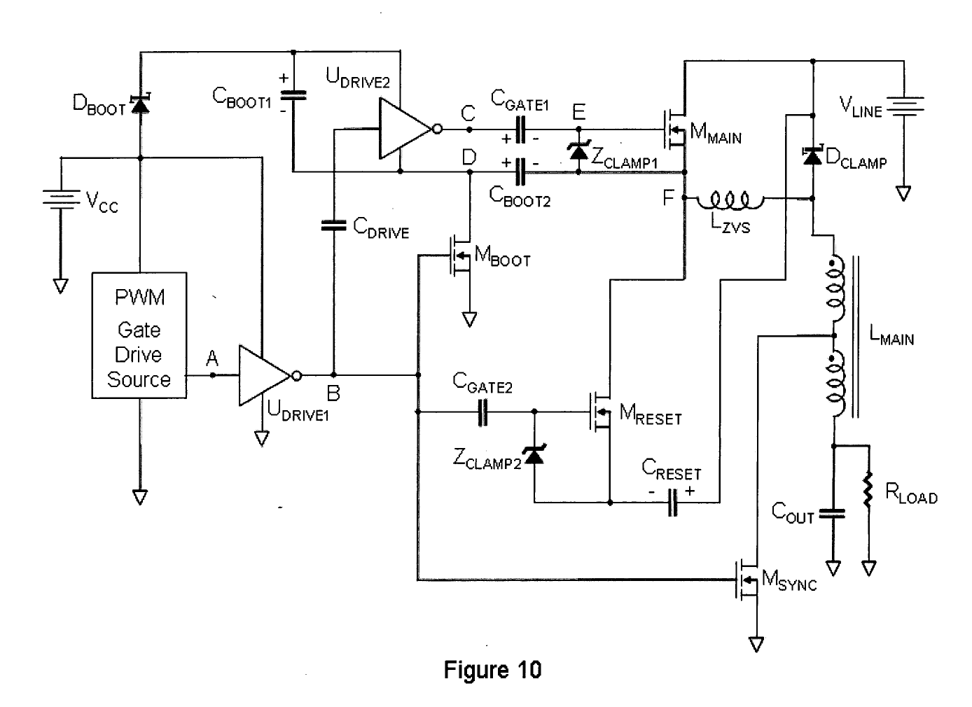

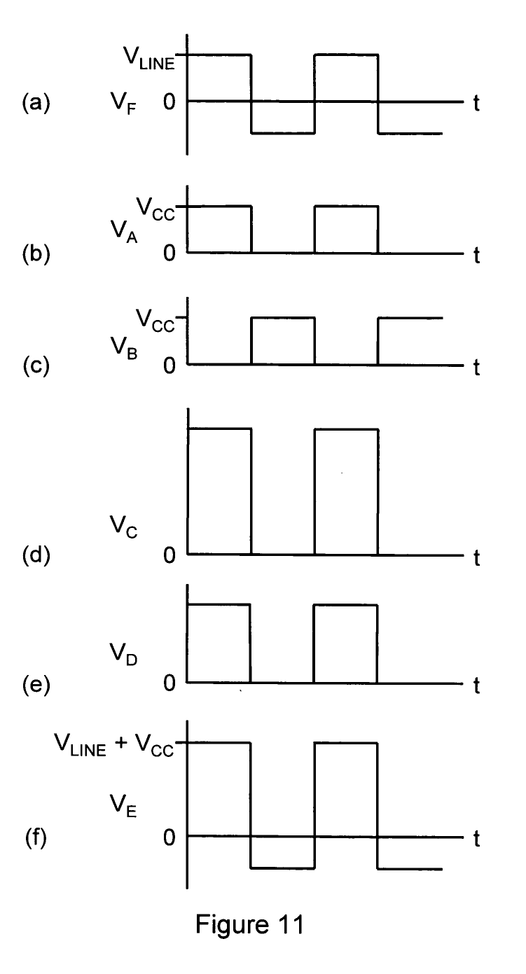

FIG. 10 illustrates a ZVS tapped inductor buck converter with a high side main switch, M_{MAIN}. One difficulty with the high side switch and the commercially available level shifting circuit drivers is that they only work if the minimum voltage of the source of the high side switch is zero volts or ground. In the ZVS tapped inductor buck converter the minimum source voltage of the high side main switch will be negative and will be line and load dependent. A wave form of the source voltage of M_{MAIN} is illustrated in FIG. 11(a). At the same time the gate to source voltage needed to drive the high side main switch is the same, in general, as the gate to source voltage needed to drive the ground referenced synchronous rectifier, M_{SYNC}, and the reset switch, M_{RESET}. In the FIG. 10 circuit the first bootstrap capacitor, C_{BOOT1}, is charged when the main switch, M_{MAIN}, is off and the source of M_{MAIN} is at a negative voltage. The desired applied voltage for C_{BOOT1} is V_{cc}, which is in the range of 10 to 15 volts for mosfets with standard gate threshold in the 2 to 4 volts range. While M_{MAIN} is off M_{BOOT}, M_{RESET}, and M_{SYNC} are on and the negative terminal of C_{BOOT1} is at ground potential. C_{BOOT1} charges from V_{CC} through D_{BOOT} and M_{BOOT} to ground so the voltage applied to C_{BOOT1} is V_{CC} minus the forward voltage of D_{BOOT}. Also while M_{MAIN} is off C_{BOOT2} is charged through M_{BOOT}, M_{RESET}, C_{RESET}, and V_{LINE}. The voltage applied to the capacitor C_{GATE1} is approximately equal to the voltage applied to C_{BOOT2} because when M_{MAIN} is off the voltage at the gate of M_{MAIN} is approximately equal to the voltage at the source of M_{MAIN} and the voltage at the output of U_{DRIVE2} at node C is the same as the voltage at node D. At the beginning of the on transition for M_{MAIN} the voltage at node A rises to V_{cc}, the voltage at node B drops to ground, thereby turning off M_{BOOT}, M_{RESET}, and M_{SYNC}, the voltage at node C rises to a level in the range of 10 to 15 volts above node D, and the voltage at node E rises to a level in the range of 10 to 15 volts above the level at node F, enhancing the gate of M_{MAIN} which turns M_{MAIN} on. Wave forms illustrating the voltages of nodes A, B, C, D, and E are illustrated in FIG. 11(b), FIG. 11(c), FIG. 11(d), FIG. 11(e), and FIG. 11(f), respectively. The voltage rating of Z_{CLAMP1} is equal to V_{CC} so that the operating range of the gate to source voltage of M_{MAIN} is zero volts to V_{CC}. The gate to source voltage operating range for the other three power mosfets is the same as for M_{MAIN}.

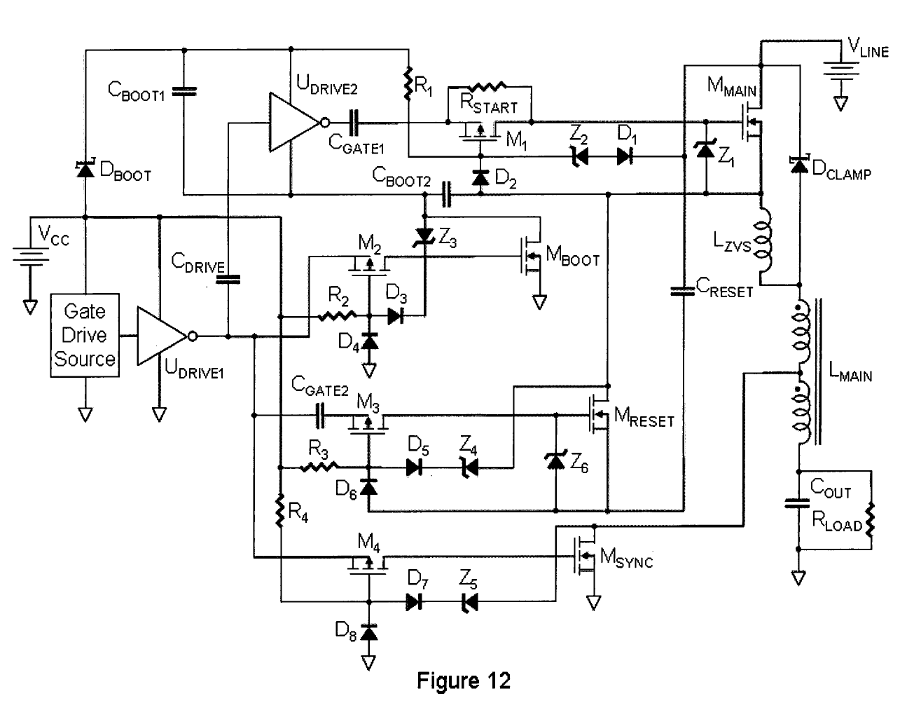

FIG. 12 illustrates a tapped inductor buck converter similar to that shown in FIG. 10, but with the gate drive circuit of FIG. 6 added to optimize the gate timing in order to truly achieve the zero voltage switching results of which the converter is capable.

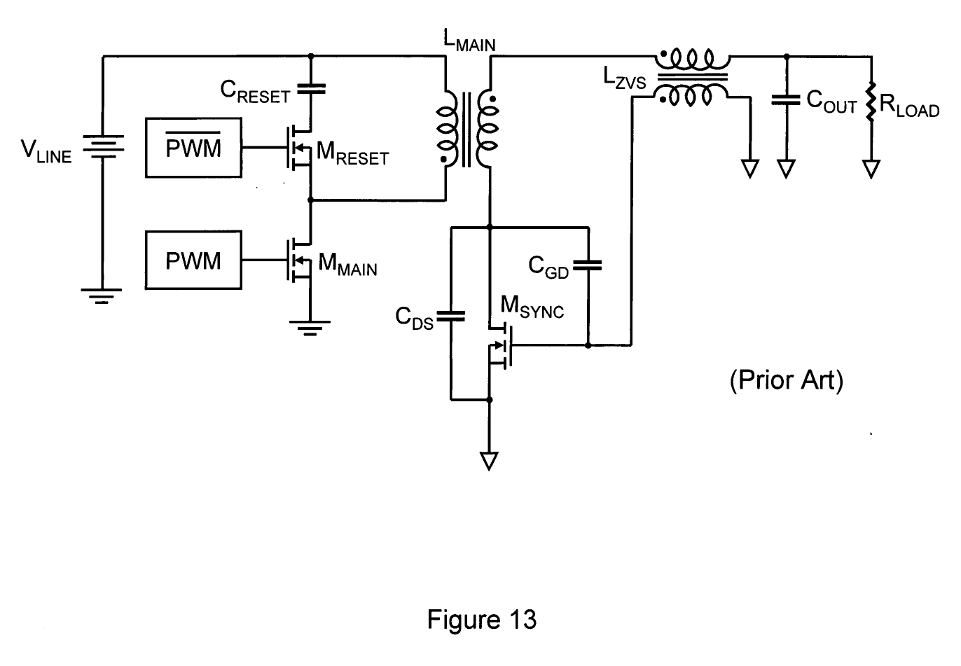

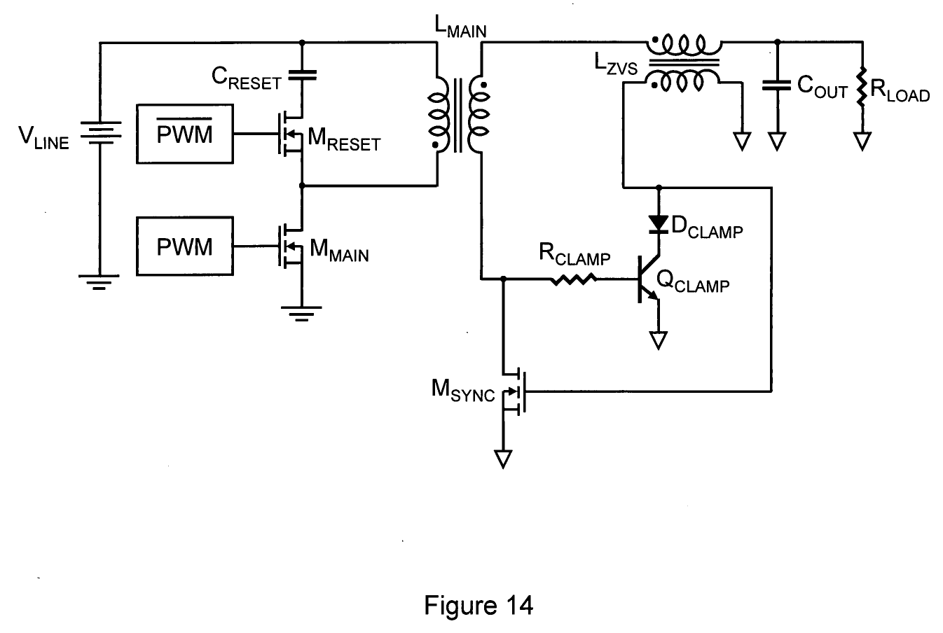

FIG. 13 illustrates a ZVS active clamp flyback converter with secondary side placed ZVS drive choke with an extra winding to drive the gate of the synchronous rectifier. Using a winding on the ZVS drive choke to drive the synchronous rectifier has some significant advantages since it obviates transferring gate drive timing information across the isolation boundary and the energy needed to drive the gate of the synchronous rectifier is provided at a suitable level simply by choice of turns on the extra choke winding. With a primary side placement of the choke, clamping ringing and overshoot associated with the choke is a simple and straight forward matter and the problem is easily solved with a single rectifier. A similar solution for the secondary side placement is not at all obvious. FIG. 14 provides a relatively simple solution to this problem. The problem is ringing and overshoot associated with the L_{ZVS} choke and the parasitic capacitances in the secondary circuit. Also, with the secondary side placement of the ZVS drive choke and the use of a secondary winding of the ZVS drive choke to drive the gate of the synchronous rectifier the overshoot can cause the inadvertent turn on of the synchronous rectifier at the peak of the overshoot, which can lead to a catastrophic failure. The principal secondary capacitances are associated with the output capacitance of the synchronous rectifier and the intrawinding capacitance of the secondary winding of L_{MAIN}. The problem occurs only when the synchronous rectifier, M_{SYNC}, is off. When M_{SYNC} is off the drain voltage of M_{SYNC} is positive so that there will be a current flowing in R_{CLAMP}, forward biasing the base emitter junction of Q_{CLAMP} and Q_{CLAMP} will be on. During the turn off transition of M_{SYNC} the undotted terminals of L_{ZVS} are positive in voltage with respect to the undotted terminals so that the rectifier D_{CLAMP} will be reverse biased and no current will flow in the collector of Q_{CLAMP}. When M_{SYNC} is turned off its drain voltage rises charging the output capacitance of M_{SYNC} with a current that flows through the main winding of L_{ZVS} from undotted terminal to dotted terminal. When the winding voltage of L_{ZVS} reaches zero volts the rectifier D_{CLAMP} becomes forward biased and current begins to flow in the collector of Q_{CLAMP}. D_{CLAMP} and Q_{CLAMP} prevent the voltages at the dotted terminals of L_{ZVS} from rising above the voltages at the undotted terminals of L_{ZVS} which prevents overshoot and ringing at the drain of M_{SYNC}, which is the desired result.

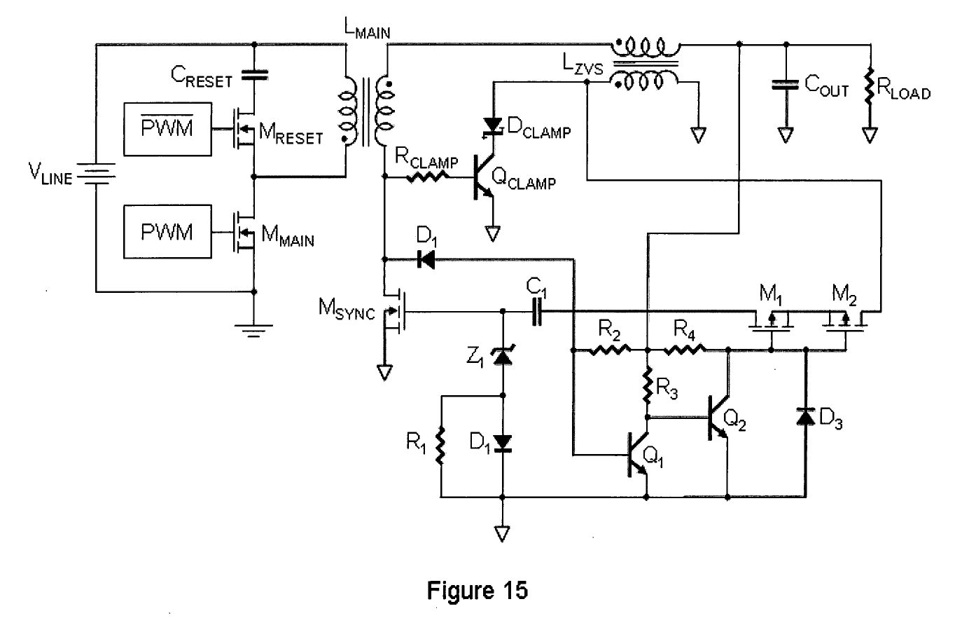

FIG. 15 illustrates the clamp circuit of FIG. 14 used together with the gate drive circuit of FIG. 3 to provide a gate drive circuit for the synchronous rectifier which is properly timed and free of overshoot and ringing. An additional P channel mosfet M₂ is provided that limits the gate voltage swing of M_{SYNC} to an acceptable range while providing sufficient drive voltage to fully enhance M_{SYNC} for all conditions except no load and very light loading. At no load and very light loading the consequences of not fully enhancing the synchronous rectifier are small or insignificant since the losses associated with the very small currents are small or insignificant.

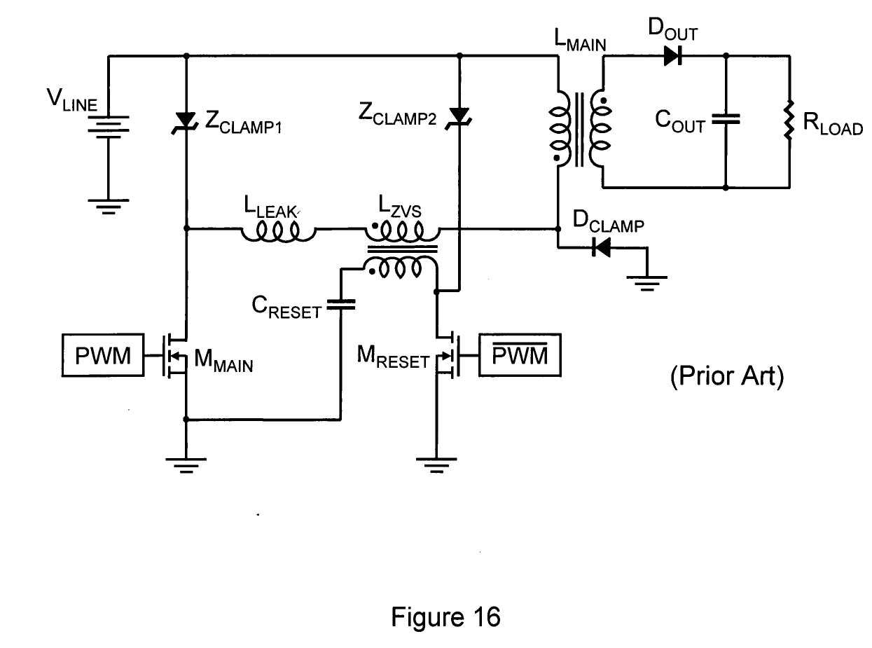

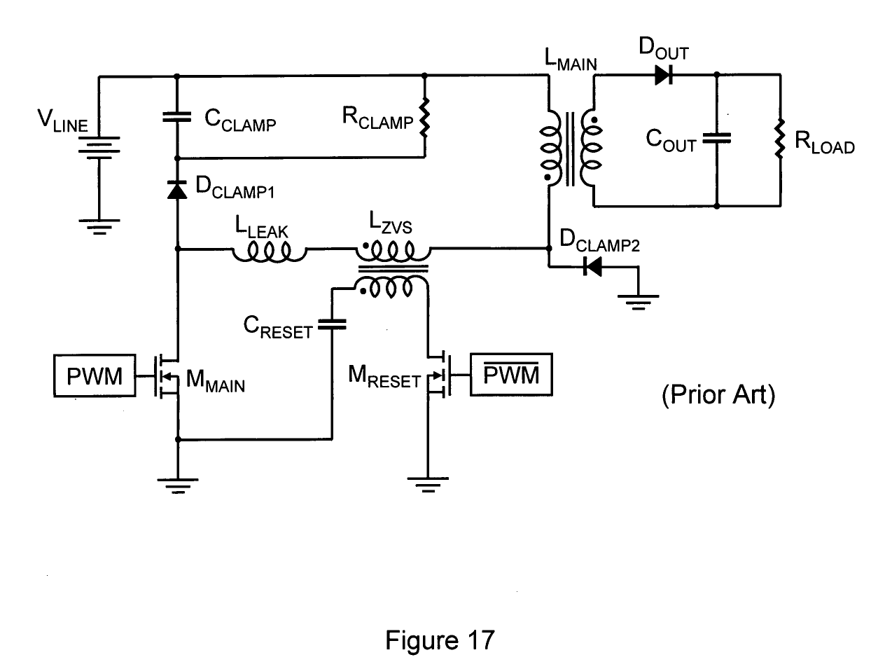

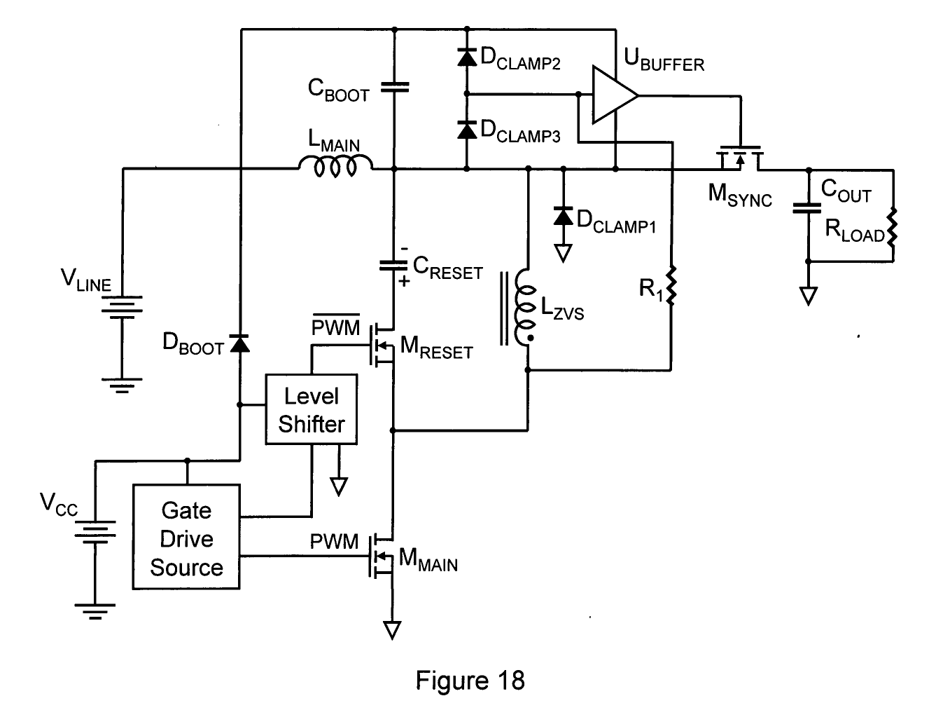

FIG. 16 and FIG. 17 illustrate two methods of clamping leakage inductance in a ZVS active reset flyback converter with only low side driven power switches. What is needed is a simple method to drive a switch that does not have a ground reference without the requirement for a gate drive transformer or level shifting circuits. One method of accomplishing this feat in ZVS circuits that use a small auxiliary choke for an energy source to drive a zero voltage switching transition for a main switch was revealed in U.S. Pat. No. 6,650,550. This method uses a winding of the small auxiliary choke as a source of both timing information and gate drive energy. Using the small choke for gate drive energy creates some problems since the range of voltages generated by a winding of the auxiliary choke varies considerably from no load to full load. In some cases it will be more simple to use an alternate source of energy to drive the switch that is not ground referenced but to use the timing information provided by the small auxiliary choke. A circuit that uses the timing information from the auxiliary choke but derives its energy for gate drive from a boot strap circuit to drive a synchronous rectifier is illustrated in FIG. 18. FIG. 18 illustrates a ZVS boost converter with a synchronous rectifier. The choke L_{ZVS} provides energy during the turn on transition of the main switch M_{MAIN} to drive M_{MAIN} to zero volts thereby eliminating turn on switching losses for M_{MAIN} and increasing the efficiency and reliability of the power converter. Details of the ZVS operation of the FIG. 18 boost converter can be found in U.S. Pat. No. 6,452,814. In FIG. 18 M_{SYNC} is driven by an integrated circuit driver IC, U_{BUFFER}, such as a TPS2829, and the energy for driving M_{SYNC} is provided by a bootstrap circuit consisting of D_{BOOT} and C_{BOOT}. Timing information is provided to U_{BUFFER} from L_{ZVS} via a resistor, R₁. Rectifiers D_{CLAMP1} and D_{CLAMP2} protect the input of U_{BUFFER} from voltages outside the normal operating range of U_{BUFFER}. Since U_{BUFFER} has a very high input resistance a relatively large value resistor can be used for R₁ so that power losses in R₁ will be small or insignificant. In general the dotted terminal of L_{ZVS} will be high with respect to the undotted terminal of L_{ZVS} when M_{SYNC} needs to be on and the dotted terminal of L_{ZVS} will be low or zero with respect to the undotted terminal of L_{ZVS} when M_{SYNC} needs to be off thereby providing the proper switch timing information for M_{SYNC}.

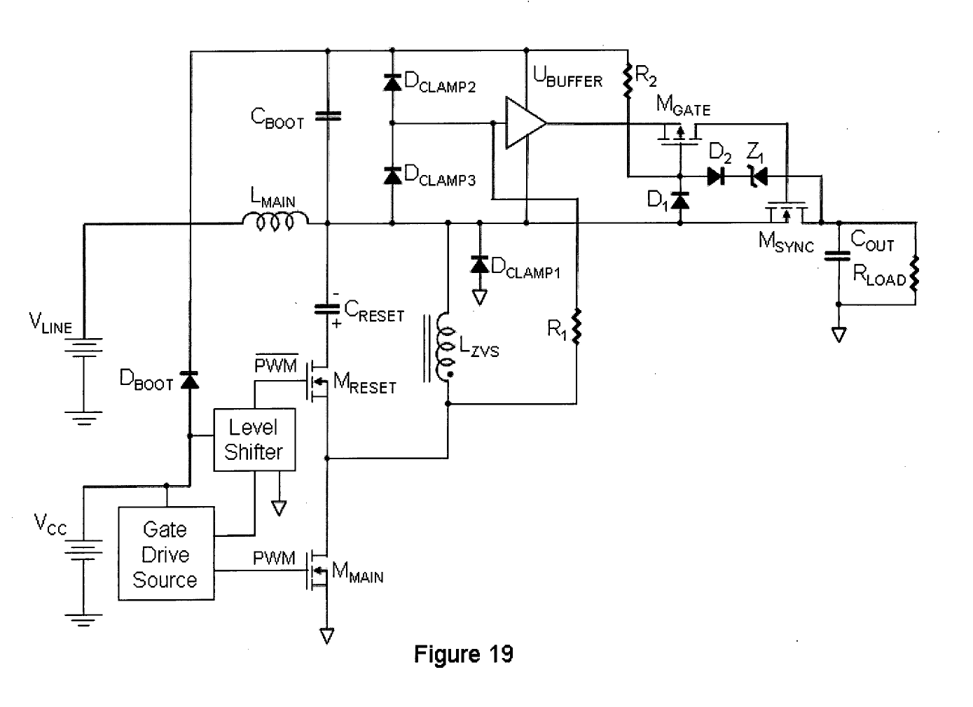

FIG. 19 illustrates another embodiment of the subject invention similar to that illustrated in FIG. 18. In the FIG. 19 embodiment the gate driver circuit of FIG. 6 is added to provide the proper timing for zero voltage switching of the synchronous rectifier M_{SYNC}.

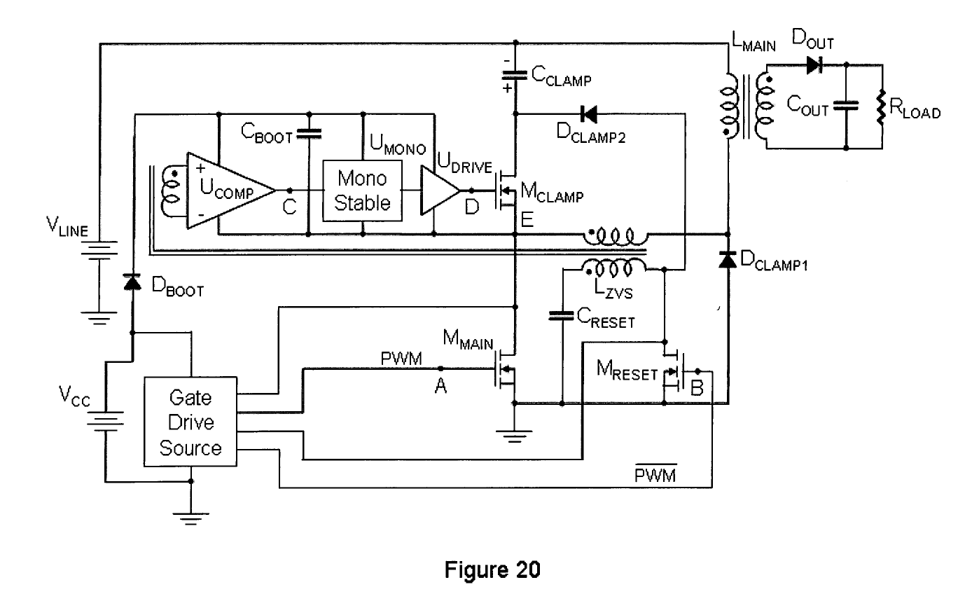

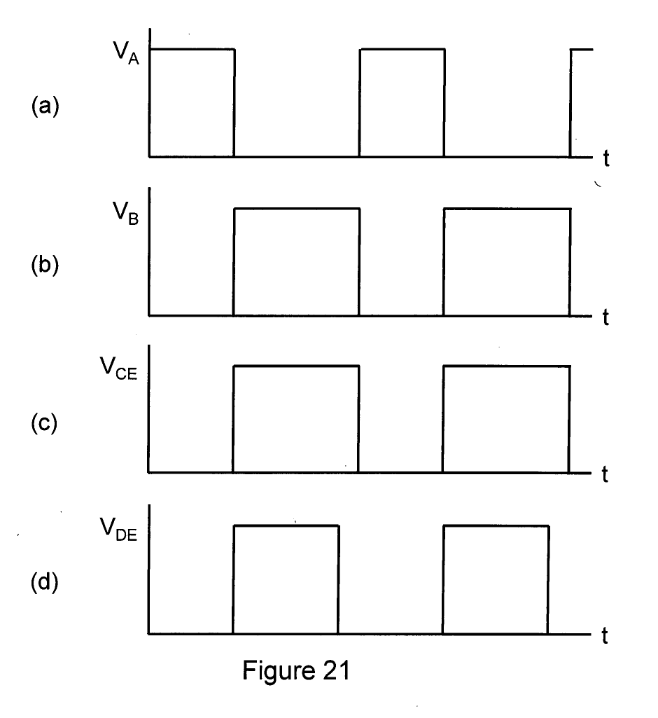

FIG. 20 illustrates another embodiment of the subject invention wherein a winding of L_{ZVS}, the auxiliary choke used for drive energy for a ZVS turn on transition of M_{MAIN}, is used to provide timing information for an active clamp switch in a ZVS active reset flyback converter. Here a winding of L_{ZVS} is used to set the output state of a comparator. The comparator output in this case must be fed to a monostable multivibrator which sets the turn off time for the clamp switch M_{CLAMP} so that the turn on timing is initiated by the winding voltage of L_{ZVS}, but the turn off timing is set by the monostable multivibrator. The monostable multivibrator is necessary in this case because the clamp switch must be off prior to the turn off of the reset switch, M_{RESET}. Otherwise M_{CLAMP} will delay or prevent the turn on transition of M_{MAIN} which is initiated by the turn off of M_{RESET}, after which energy from L_{ZVS} is released to drive the drain voltage of M_{MAIN} to zero. In FIG. 20 the gate drive circuit for M_{CLAMP} is powered from D_{BOOT} and C_{BOOT} and the timing information is provided by L_{ZVS} and the monostable multivibrator U_{MONO}. The monostable multivibrator U_{MONO} generates a pulse of fixed duration. The pulse duration will, in general, depend on the switching period and the maximum duty cycle of the main switch. If the maximum duty cycle is 60% and the switching period is 10 microseconds then the maximum pulse duration for the monostable should be set to slightly less than 4 microseconds so that in all cases M_{CLAMP} will already be off when M_{RESET} is turned off. Since the amount of energy processed through M_{CLAMP} and C_{CLAMP} is small the shorter duration of the on time of M_{CLAMP} should have no significant impact. It is usually helpful to set C_{CLAMP} smaller than C_{RESET} so that the primary energy exchange of L_{ZVS} during the off time of M_{MAIN} is with C_{RESET} rather than with C_{CLAMP}. Reset current for L_{ZVS} will flow into C_{CLAMP} and C_{RESET} in proportion to the relative capacitances of C_{CLAMP} and C_{RESET}. There are no consequences to having C_{CLAMP} and C_{RESET} of roughly equal values if the size of M_{CLAMP} and M_{RESET} are roughly equal, but if C_{CLAMP} is much smaller than C_{RESET} then M_{CLAMP} can be much smaller than M_{RESET}. FIGS. 21(a) through 21(d) illustrates the gate voltage wave forms for the active switches in FIG. 20.

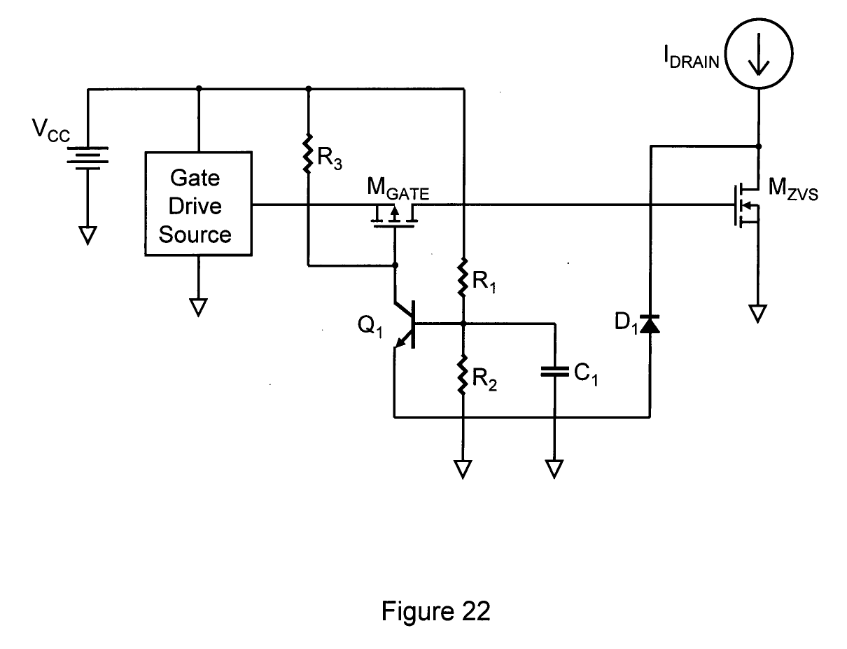

FIG. 22 illustrates a gate drive circuit for achieving optimal turn on timing of a zero voltage switch. During a turn on transition the drain voltage of M_{ZVS} is positive with respect to ground but the drain voltage is falling towards ground. Rectifier D₁ is reverse biased so no current flows in D₁ or in the transistor Q₁ until the drain voltage of M_{ZVS} reaches ground potential at which time D₁ becomes forward biased and the base emitter junction of Q₁ becomes forward biased and the gate of P channel mosfet M_{GATE} is pulled low which enables current to flow to the gate of M_{ZVS}, turning M_{ZVS} on.

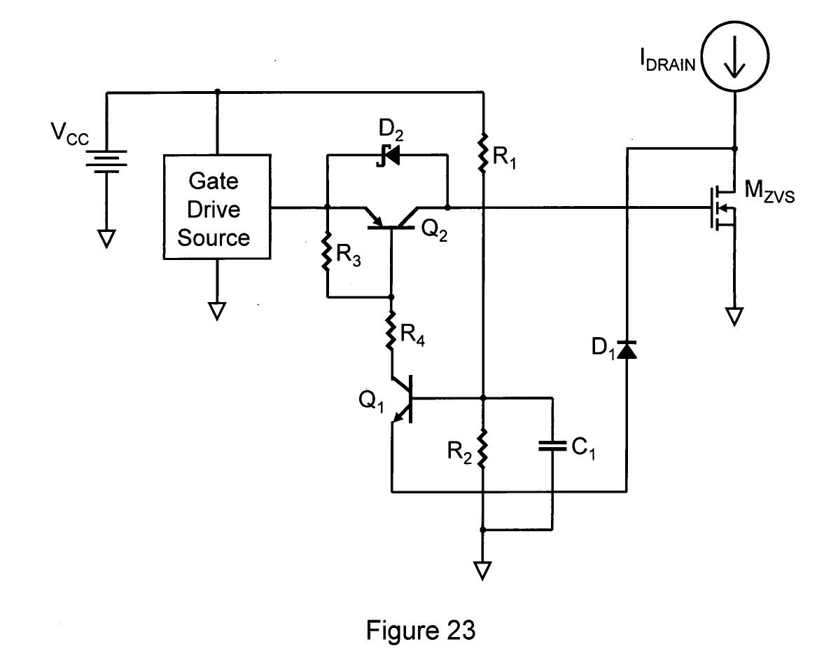

FIG. 23 illustrates a variation of the FIG. 22 circuit wherein a PNP bipolar transistor Q₂ and a schottky rectifier D₂ is substituted for the P channel mosfet M_{GATE}. In both FIG. 23 and FIG. 22 it is necessary to bias the base of Q₁ at a voltage greater than two forward junction drops above ground in order for Q₁ to conduct reliably through the entire transition. A small value (a few picofarads to a few tens of picofarads) capacitor C₁ is optional and can be used to speed up the turn on transition.

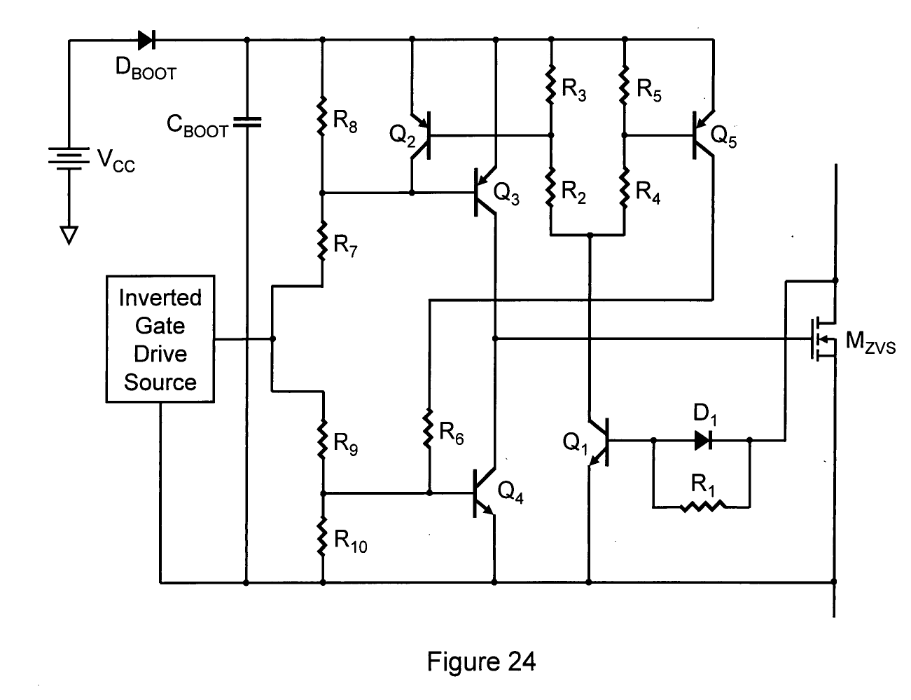

FIG. 24 illustrates a gate drive circuit for achieving optimal turn on timing of a zero voltage switch. At the start of a turn on transition the voltage at the output of the inverted gate drive source falls stopping current flow in R₉ and initiating current flow in R₇. At the beginning of the turn on transition the drain to source voltage of M_{ZVS} is positive so that rectifier D₁ is reverse biased. At the beginning of the turn on transition the base emitter junction of Q₁ is forward biased so that Q₁ is on and transistors Q₂, Q₅, and Q₄ are also on. The fact that Q₂ and Q₄ are being held on by Q₅ and Q₁ suggests that the gate of M_{ZVS} is being held off during the turn on transition up until the time that Q₁ is turned off. Q₁ will be turned off when the drain to source voltage of M_{ZVS} reaches zero volts thereby forward biasing rectifier D₁ and reverse biasing the base emitter junction of Q₁. With Q₁ off, Q₂ and Q₄ turn off and Q₃ turns on driven by current from R₇, enabling current into the gate of M_{ZVS}, turning M_{ZVS} on at zero volts, as desired.

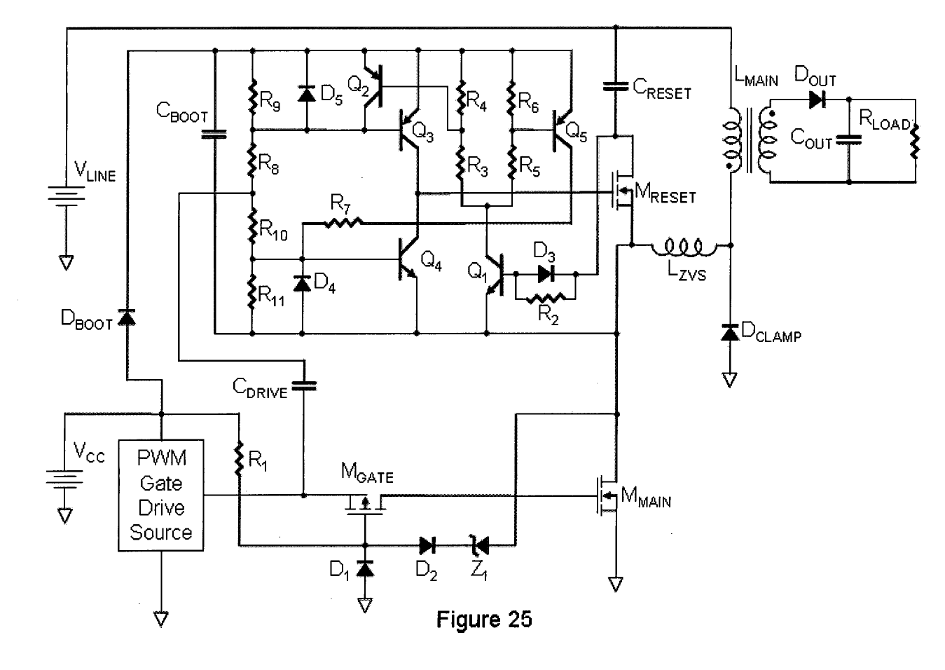

FIG. 25 illustrates the application of the FIG. 24 gate drive circuit to a high side reset switch in a ZVS active reset flyback converter. In the FIG. 25 circuit the inverted gate drive source is just the PWM gate drive source for the main switch. Since the reset switch is operated in anti-synchronization to the main switch no additional inversion is required.

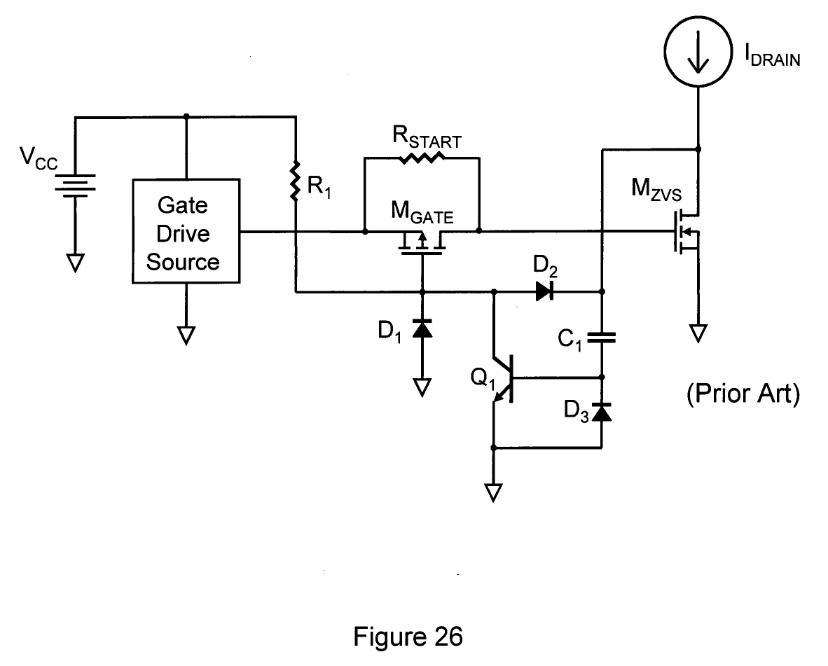

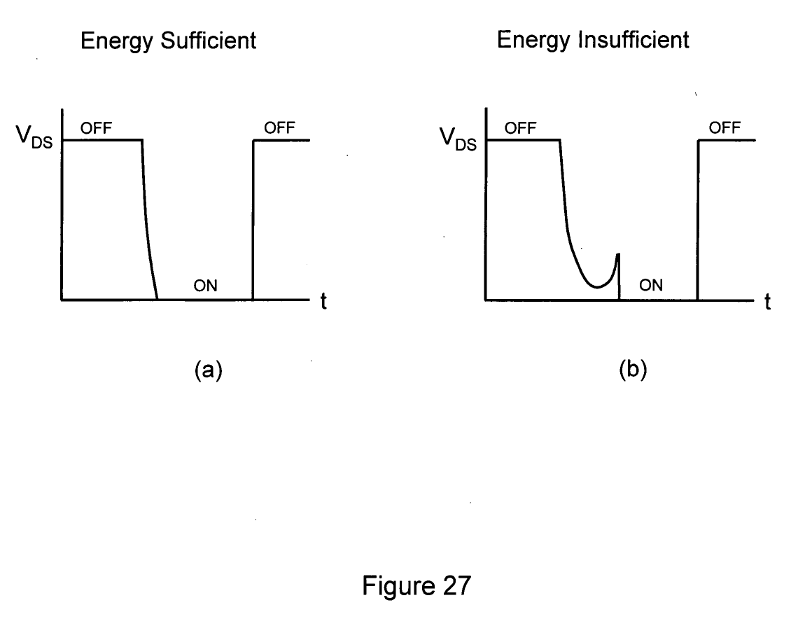

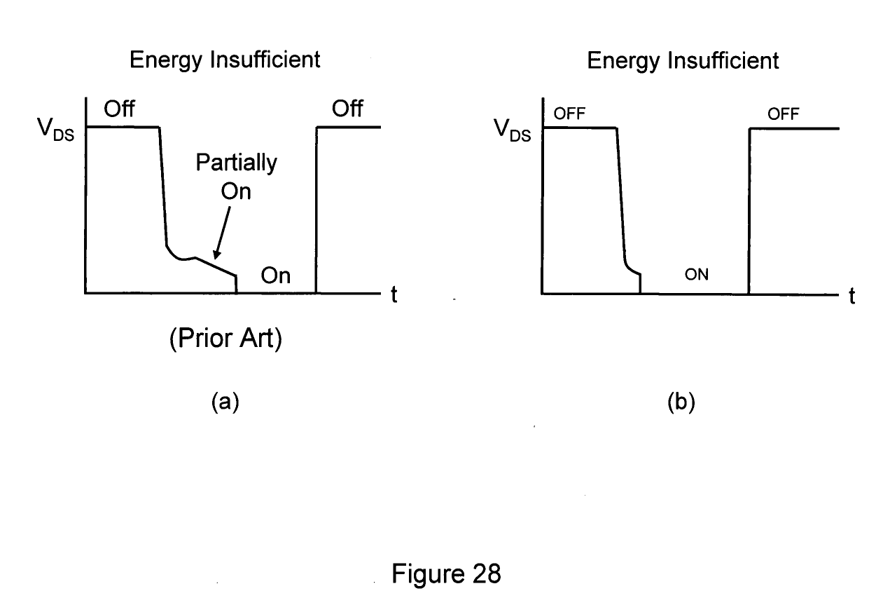

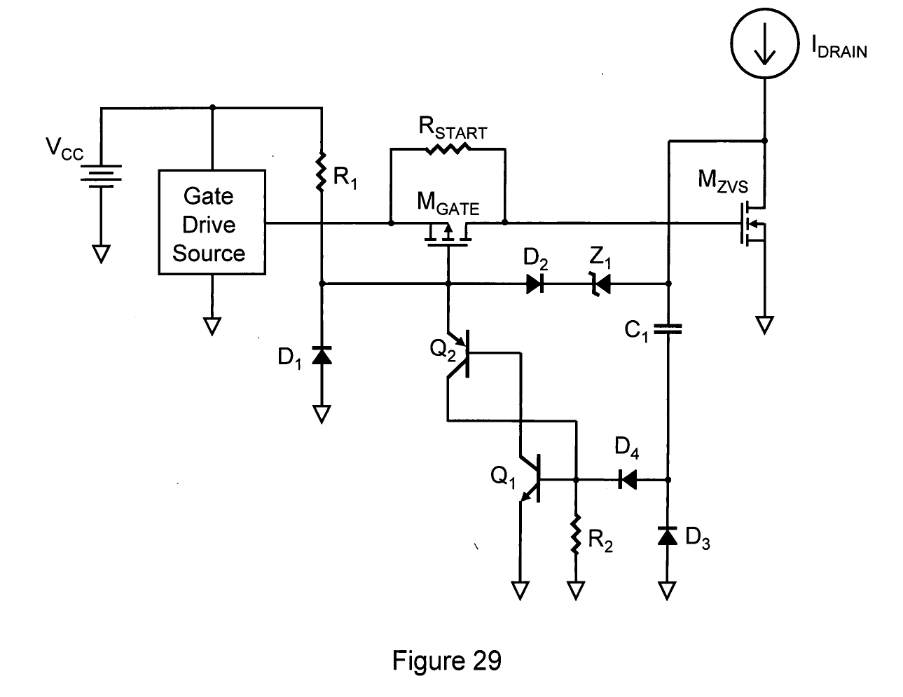

FIG. 26 illustrates a prior art gate drive circuit that can be used for optimal gate drive timing for the situation in which there is insufficient drive energy available to drive the drain voltage of a zero voltage switch all the way down to the source voltage. The difference between an energy sufficient transition and a transition with insufficient energy is illustrated in FIG. 27(a) and FIG. 27(b). In the energy sufficient transition, illustrated in FIG. 27(a), the drain source voltage falls all the way to zero volts during a turn on transition, but in the insufficient energy transition, illustrated in FIG. 27(b), the drain source voltage falls to the point where the available drive energy has been fully depleted and then the drain source voltage reverses direction and rises up again. For an energy insufficient transition, as illustrated in FIG. 27(b), switching losses are substantial and converter efficiency and reliability are degraded. The FIG. 26 circuit provides a simple solution in which the rate of change of the drain to source voltage is detected by the capacitor C₁, diode D₃, and transistor Q₁, so that when the drain source voltage ramp changes direction Q₁ becomes forward biased leading to a turn on of the power switch M_{ZVS}. There is a minor problem which can occur wherein the initiation of the turn on of the main switch M_{ZVS} causes the drain voltage to stop rising and begin to fall again causing a reversal of current direction in the C₁ capacitor which disables the transistor Q₁ thereby stopping the turn on of the main switch M_{ZVS}. The resulting drain source voltage is illustrated in FIG. 28(a). In this situation there is a negative feedback loop which acts to slow down the turn on of the main switch M_{ZVS}. The circuit illustrated in FIG. 29 provides a solution to the negative feedback problem that results in the turn on characteristic illustrated by FIG. 28(a). In the FIG. 29 circuit, when the drain source voltage of the main switch M_{ZVS} reaches a minimum voltage and then begins to increase, the diode D₄ and the base emitter junction of Q₁ become forward biased. Turning on Q₁ results in the turn on of Q₂ which provides base current into Q₁ through the collector terminal of Q₂, latching both Q₁ and Q₂ on until the gate terminal voltage of M_{GATE} falls to zero volts (ground). Reducing the gate voltage of M_{GATE} turns M_{GATE} on which enables current into the gate terminal of M_{ZVS} turning M_{ZVS} on. When the drain source voltage of M_{ZVS} falls D₄ blocks the C₁ current from reverse biasing the Q₁ base emitter junction which remains forward biased by current from the collector of Q₂. Once Q₁ begins to conduct current, the turn on transition of M_{ZVS} is completed with no negative feedback effects, as illustrated in FIG. 28(b). Once current from C₁ initiates a turn on transition, the transition proceeds quickly to completion with no dependence on subsequent current in C₁. The negative feedback problems that can sometimes occur in the FIG. 26 circuit are eliminated in the FIG. 29 circuit.

### CONCLUSION, RAMIFICATIONS, AND SCOPE OF INVENTION

Thus the reader will see that a simple circuit comprising a rectifier and transistors can provide optimal turn on timing for a zero voltage switch. The reader will also see that the addition of a zener diode or transistor to a prior art gate drive circuit for optimal switch turn on timing will prevent premature turn on of the zero voltage switch. The reader will also see that gate drive circuits for high side switches whose source or reference terminals swing both above and below ground can be powered from simple boot strap circuits comprising a rectifier, a ground referenced switch, a few capacitors, and a simple clamp circuit. The reader will also see that a prior art secondary side gate drive circuit relying on a winding of an auxiliary choke can be improved with a simple clamp circuit comprising a transistor and a rectifier. The reader will also see that switch timing information for synchronous rectifiers and clamp switches can be derived from an auxiliary inductor used to provide energy for driving a zero voltage switch. The reader will also see that a gate drive circuit with optimal turn on timing that holds the switch off while there is applied drain source voltage for an inverted gate drive source can be constructed from a circuit comprising a rectifier and five transistors. The reader will also see that a prior art circuit for providing optimal turn on timing for a zero voltage switch when there is insufficient drive energy available to drive the switch to zero volts can be improved by the addition of a diode and a transistor to latch the turn on of a transistor and prevent a capacitor in the circuit from turning off the transistor when the circuit is triggered.

While my above description contains many specificities, these should not be construed as limitations on the scope of the invention, but rather, as exemplifications or preferred embodiments thereof. Many other variations are possible. For example, complementary gate drive circuits for P channel power switches are possible. Circuits of the type shown but with enhancement mode mosfets substituted for bipolar transistors, or vice versa, are possible. Accordingly, the scope of the invention should be determined not by the embodiments illustrated, but by the appended claims and their legal equivalents.

1. A gate drive circuit coupleable to a zero voltage switch comprising,
a first resistor,
a rectifier having a first terminal connected to a drain terminal of said zero voltage switch and a second terminal connected to a first terminal of said first resistor,
a first transistor having a control terminal connected to said first terminal of said resistor and having a first main terminal connected to a source terminal of said zero voltage switch,
a second resistor having a first terminal and a second terminal with said first terminal connected to a second main terminal of said first transistor,
a second transistor having a control terminal connected to said second main terminal of said first transistor and having a first main terminal connected to said first main terminal of said first transistor,
inverting gate control means having a first main terminal coupleable to a controlled source of gate drive power, having a second main terminal coupleable to a gate terminal of said zero voltage switch, and having a control terminal coupleable to a second main terminal of said second transistor,
whereby said first resistor conducts current turning on said first transistor when said zero voltage switch has a voltage greater than zero applied between its drain and source terminals thereby keeping said second transistor in an off state and said inverting gate control means in an off state, and said rectifier becomes forward biased turning off said first transistor and turning on said second transistor enabling said inverting gate control means and enhancing said gate terminal of said zero voltage switch when said applied voltage across said zero voltage switch is less than or substantially equal to zero volts.

2. A gate drive circuit for optimal turn on timing of a zero voltage switch comprising,
inverting gate control means having a first main terminal coupleable to a controlled source of gate drive power and voltage and a second main terminal coupleable to a gate terminal of said zero voltage switch,
a first rectifier having a first terminal coupleable to a source terminal of said zero voltage switch and having a second terminal coupleable to a control terminal of said inverting gate control means,
a diode network having a first terminal connected to said control terminal of said inverting gate control means and a second terminal connected to a drain terminal of said zero voltage switch comprising a series connection of,
a second rectifier, and
a zener diode,
whereby during a turn on transition of said zero voltage switch said inverting gate control means prevents gate drive turn on voltage from being applied to said gate terminal of said zero voltage switch until the applied drain source voltage of said zero voltage switch has fallen to substantially zero volts at which time said second rectifier begins to conduct and said zener diode begins to avalanche, changing the voltage at said control terminal of said inverting gate control means, allowing said inverting gate control means to conduct charge to said gate terminal of said zero voltage switch, thereby achieving optimal turn on timing for said zero voltage switch.

3. The gate drive circuit of claim 2 in which said inverting gate control means is a mosfet.

4. The gate drive circuit of claim 2 in which said inverting gate control means is a bipolar transistor.

5. A floating gate drive circuit for a power switch which has a source or reference terminal that swings both above ground and below ground comprising,
a gate buffer capable of providing sufficient voltage to fully enhance said power switch and sufficient current capability to fully discharge a control terminal of said power switch in a time interval less than 5% of a switching period,
a source of gate timing information coupleable to said gate buffer,
a source of gate drive energy referenced to a ground,
a rectifier having a first terminal connected to said source of gate drive energy,
a first capacitor having a first terminal connected to a second terminal of said rectifier,
a second capacitor having a first terminal coupleable to an output of said gate buffer and having a second terminal coupleable to a control terminal of said power switch,
switch means having a control terminal coupleable to said source of gate timing information, a first main terminal connected to ground, and a second main terminal connected to a second terminal of said first capacitor,
a third capacitor having a first terminal connected to said second main terminal of said switch means and having a second terminal connected to a reference terminal of said power switch,
voltage clamping means having a first terminal connected to said control terminal of said power switch and having a second terminal connected to said reference terminal of said power switch,
whereby said switch means and said rectifier enable charging of said first capacitor to a peak-to-peak ac voltage suitable for driving said power switch and said switch means together with said voltage clamping means applies a voltage to said second and third capacitors substantially equal to the peak negative voltage of said reference terminal of said power switch thereby providing a suitable mechanism for switching on and switching off said power switch when operating over a voltage range in which said reference terminal of said power switch swings between a voltage below ground and a voltage above ground as said power switch is turned off and on, respectively.

6. The floating gate drive circuit of claim 5 further comprising the gate drive circuit of claim 2 thereby providing an optimally timed turn on mechanism for said power switch when there is sufficient energy available to drive said power switch to zero volts.

7. A clamped gate drive circuit for a synchronous rectifier comprising,
an auxiliary coupled inductor having at least a main winding and a secondary winding, which serves as a source of energy for driving a zero voltage turn on transition of a main switch in a power converter, wherein an undotted terminal of said main winding of said auxiliary coupled inductor is coupleable to an output of said power converter and an undotted terminal of said secondary winding of said auxiliary coupled inductor is connected to a source terminal of said synchronous rectifier,
a resistor having a first terminal connected to a drain terminal of said synchronous rectifier,
a transistor having a control terminal connected to a second terminal of said resistor and having a first main terminal connected to said source terminal of said synchronous rectifier,
a rectifier having a first terminal connected to a dotted terminal of said secondary winding of said auxiliary coupled inductor and having a second terminal connected to a second main terminal of said transistor,
whereby said dotted terminal of said secondary winding of said auxiliary coupled inductor provides a gate drive signal for said synchronous rectifier and said rectifier and transistor provides a mechanism for limiting the maximum applied voltage of said synchronous rectifier and a mechanism for eliminating ringing associated with said auxiliary coupled inductor and intrinsic capacitance of said synchronous rectifier and for eliminating inadvertent turn on of said synchronous rectifier during an off state of said synchronous rectifier.

8. The clamped gate drive circuit of claim 7 further comprising the gate drive circuit of claim 1 thereby providing an optimally timed gate drive turn on mechanism for said synchronous rectifier.

9. A gate drive circuit for a zero voltage switch comprising,
an auxiliary coupled inductor, which serves as a source of energy for driving a zero voltage turn on transition of a main switch in a power converter,
a source of gate drive energy independent of said auxiliary coupled inductor having a first terminal coupleable to a reference terminal of said zero voltage switch and having sufficient voltage to enhance said zero voltage switch,
a buffer having a control terminal coupleable to a winding of said auxiliary coupled inductor and having a pair of power terminals connected to said source of gate drive energy and having an output terminal coupleable to a control terminal of said zero voltage switch, having sufficient current drive capability to discharge said control terminal of said zero voltage switch in a time interval less than 5% of a switching period of said power converter,
whereby said gate drive circuit provides a simple means of zero voltage switch gate drive without an additional magnetic signal coupling element or level shifting gate drive circuits.

10. The gate drive circuit of claim 9 further comprising the gate driver circuit of claim 2 thereby providing an optimally timed gate drive turn on mechanism for said zero voltage switch.

11. The gate drive circuit of claim 9 wherein the zero voltage switch is a clamp circuit rectifier.

12. The gate drive circuit of claim 11 further comprising a monostable multivibrator connected between said input to said buffer and said auxiliary coupled inductor whereby said monostable multivibrator reduces the on time of said clamp circuit rectifier so that said auxiliary coupled inductor winding voltage timing is not effected by said gate drive circuit.

13. A gate drive circuit for optimal turn on timing of a zero voltage switch comprising,
a controlled source of gate drive power and voltage having sufficient voltage to enhance said zero voltage switch,
a rectifier having a first terminal and a second terminal with said first terminal of said rectifier connected to a drain terminal of said zero voltage switch,
a first transistor having a control terminal coupleable to a source terminal of said zero voltage switch and having a first main terminal connected to said second terminal of said rectifier,
a second transistor having a control terminal coupleable to a second main terminal of said first transistor, a first main terminal coupleable to said controlled source of gate drive power and voltage and a second main terminal coupleable to a gate terminal of said zero voltage switch,
whereby said rectifier begins to conduct when applied voltage to said zero voltage switch falls to zero volts thereby turning on said first and second transistors and enabling gate drive voltage to said gate terminal of said zero voltage switch accomplishing optimal timing of said zero voltage switch.

14. A gate drive circuit for optimal turn on timing of a zero voltage switch comprising,
a rectifier having a first terminal connected to a drain terminal of said zero voltage switch,
a first transistor having a control terminal connected to a second terminal of said rectifier and a first main terminal coupleable to a source terminal of said zero voltage switch,
a source of dc potential having a first terminal connected to a source terminal of said zero voltage switch,
a second transistor having a control terminal coupleable to a second main terminal of said first transistor and having a first main terminal connected to a second terminal of said source of dc potential,
a third transistor having a control terminal connected to a second main terminal of said second transistor and having a first main terminal connected to said first main terminal of said second transistor and having a second main terminal coupleable to a gate terminal of said zero voltage switch,
an inverted gate drive control source coupleable to said control terminal of said third transistor,
a fourth transistor having a control terminal coupleable to said inverted gate drive control source and having a first main terminal connected to said source terminal of said zero voltage switch and having a second main terminal connected to said second main terminal of said third transistor,
a fifth transistor having a control terminal coupleable to said second main terminal of said first transistor and having a first main terminal connected to said first main terminal of said second transistor and having a second main terminal coupleable to said control terminal of said fourth transistor,
whereby said rectifier begins to conduct when applied voltage to said zero voltage switch falls to zero thereby turning off said first transistor and enabling a turn on of said third transistor in the presence of a low signal from said inverted gate drive control source and whereby said first transistor conducts turning on said second, fourth, and fifth transistors thereby disabling said third transistor and said zero voltage switch in the presence of non-zero voltage applied to said zero voltage switch.

15. I claim a gate drive circuit for optimal turn on timing of a power switch comprising,
a capacitor having first and second terminals with said first terminal connected to a drain terminal of said power switch,
a first rectifier having a first terminal connected to a source terminal of said power switch and having a second terminal connected to a second terminal of said capacitor,
a second rectifier having a first terminal connected to said second terminal of said capacitor,
a first transistor having a control terminal connected to a second terminal of said second rectifier and having a first main terminal connected to said first terminal of said first rectifier,
a second transistor having a control terminal coupleable to a second main terminal of said first transistor and having first and second main terminals with said second main terminal coupleable to said control terminal of said first transistor,
a controlled source of gate drive voltage and energy,
inverting gate control means having a control terminal coupleable to said first main terminal of said second transistor and having a first main terminal coupleable to said controlled source of gate drive voltage and energy and having a second main terminal coupleable to a gate terminal of said power switch,
whereby said gate drive circuit provides optimal turn on timing for said power switch when there is insufficient energy available to complete a zero voltage turn on transition of said power switch, turning on said power switch at the point of minimum voltage to minimize turn on switching losses and latching said first transistor so that turn on is completed without a time delay associated with negative feedback applied through said capacitor.

16. The gate drive circuit of claim 15 further comprising the gate drive circuit of claim 2 thereby providing a composite gate drive circuit with optimal timing for turn on transitions with insufficient available energy to complete the transition to zero voltage and optimal timing for turn on transitions with sufficient available energy to complete the transition to zero volts.
